(19) United States
(12) Patent Application Publication
(10) Pub. No.: US 2023/0341591 A1
(43) Pub. Date: Oct. 26, 2023

(54) OPTICAL PLASTIC FILM, POLARIZING PLATE AND IMAGE DISPLAY DEVICE THAT USE SAME, AND METHOD FOR SELECTING OPTICAL PLASTIC FILM

(71) Applicant: DAI NIPPON PRINTING CO., LTD., Tokyo (JP)

(72) Inventors: Yoshiko TANAKA, Tokorozawa-shi, Saitama (US); Shosei KUBOTA, Kashiwa-shi, Chiba (JP); Hidemasa ATOBE, Moriya-shi, Ibaraki (JP); Takashi KURODA, Moriya-shi, Ibaraki (JP); Akinobu USHIYAMA, Moriya-shi, Ibaraki (JP)

(21) Appl. No.: 18/245,833

(22) PCT Filed: Sep. 30, 2021
(86) PCT No.: PCT/JP2021/036047

§ 371 Date: Mar. 17, 2023

(30) Foreign Application Priority Data
Sep. 30, 2020 (JP) 2020-166150

(51) Int. Cl. G02B 1/14; G02B 5/30; G02B 1/111

(52) U.S. Cl. CPC G02B 1/14; G02B 5/3083; G02B 1/111

(57) ABSTRACT

The present disclosure addresses the problem of providing an optical plastic film having favorable pencil hardness without an increase in the in-plane phase difference. Disclosed is an optical plastic film comprising a first surface and a second surface that is a surface on a side opposite to the first surface, wherein the plastic film has an in-plane phase difference of 300 nm or more and 1,450 nm or less, and in a region within a depth of 20 μm from the first surface in a direction from the first surface to the second surface, an average of an erosion rate is 1.4 μm/g or more.

### TECHNICAL FIELD

The present disclosure relates to an optical plastic film, a polarization plate and an image display device using the film, and a method for selecting an optical plastic film.

### BACKGROUND ART

In many cases, various optical plastic films are used for optical components of image display devices and others. For example, in an image display device with a polarization plate on a display element, a plastic film is used to protect a polarizer included in the polarization plate. As used herein, the wording “plastic film for protecting a polarizer” is sometimes referred to as a “polarizer protection film”. Further, functional films such as an anti-glare film and an antireflection film may be used in the image display device. In many cases, an optical plastic film is used as a base material for these functional films.

Plastic films for image display devices, as represented by polarizer protection films, preferably have excellent mechanical strength. For this reason, stretched plastic films are preferably used as the plastic films for image display devices.

### CITATION LIST

### Patent Literature

PTL 1: JP 2011-107198 A

### SUMMARY OF INVENTION

### Technical Problem

Since the plastic film may be used as a surface material for an image display device, it is expected to have a predetermined pencil hardness. In particular, since it is becoming standard in recent years for an image display device to have touch panel functions, it is extremely important to suppress scratches by, for instance, increasing pencil hardness.

Unfortunately, a conventional plastic film such as a plastic film of PTL 1 has insufficient pencil hardness, and accordingly the plastic film alone is easily scratched. Thus, when the plastic film of PTL 1 is used as a surface material, it is essential to form a cured film such as a hard coating layer on the plastic film.

The pencil hardness of the plastic film can be slightly improved by increasing the thickness of the plastic film.

However, if the thickness of the plastic film of PTL 1 is increased to a level at which the pencil hardness is sufficient, this goes against the trend toward a thinner image display device. Further, the plastic film of PTL 1 is intended to be a uniaxially stretched film, which causes problems such as a tendency to break in the stretch direction.

An object of the present disclosure is to provide an optical plastic film having favorable pencil hardness, a polarization plate, and an image display device without an increase in the in-plane phase difference. In addition, the present disclosure provides a simple method for selecting an optical plastic film having favorable pencil hardness without an increase in the in-plane phase difference.

### Solution to Problem

The present disclosure provides [1] to [7] as described below.
[1] An optical plastic film comprising a first surface and a second surface that is a surface on a side opposite to the first surface, wherein
the plastic film has an in-plane phase difference of 300 nm or more and 1,450 nm or less, and
in a region within a depth of 20 μm from the first surface in a direction from the first surface to the second surface, an average of an erosion rate is 1.4 μm/g or more.
[2] The optical plastic film according to [1], wherein in the region within a depth of 20 μm from the first surface in the direction from the first surface to the second surface, a ratio of variation of the erosion rate to the average of the erosion rate is 0.100 or less.
[3] The optical plastic film according to [1] or [2], when the in-plane phase difference of the plastic film is defined as Re and the phase difference in the thickness direction is defined as Rth, Re/Rth is 0.15 or less.
[4] A polarization plate comprising: a polarizer; a first transparent protective plate disposed on one side of the polarizer; and a second transparent protective plate disposed on the other side of the polarizer, wherein at least one selected from the group consisting of the first transparent protective plate and the second transparent protective plate is the optical plastic film according to any one of [1] to [3].
[5] An image display device comprising a display element and a plastic film disposed on a light emitting surface side of the display element, wherein the plastic film is the optical plastic film according to any one of [1] to [3].
[6] The image display device according to [5], comprising a polarizer between the display element and the plastic film.
[7] A method for selecting an optical plastic film comprising a first surface and a second surface that is a surface on a side opposite to the first surface, the method comprising selecting the optical plastic film satisfying the following determination conditions:
the plastic film has an in-plane phase difference of 300 nm or more and 1,450 nm or less; and
in a region within a depth of 20 μm from the first surface in a direction from the first surface to the second surface, an average of an erosion rate is 1.4 μm/g or more.

### ADVANTAGEOUS EFFECTS OF INVENTION

The optical plastic film, polarization plate, and image display device of the present disclosure can have favorable pencil hardness without an increase in the in-plane phase difference. Further, according to the method for selecting an optical plastic film of the present disclosure, the optical plastic film having favorable pencil hardness without an increase in the in-plane phase difference can be simply selected.

### BRIEF DESCRIPTION OF DRAWINGS

FIG. 1 is a schematic cross-sectional view of an instrument for measuring the erosion rate.

FIG. 2 is a diagram that depicts the state of abrasion of an optical plastic film by using a test solution containing pure water and spherical silica as jetted from a jetting section.

FIG. 3 is a schematic cross-sectional view of an embodiment of an image display device in the present disclosure.

FIG. 4 is a schematic cross-sectional view of another embodiment of the image display device in the present disclosure.

### DESCRIPTION OF EMBODIMENTS

Hereinbelow, embodiments of the present disclosure will be described.

### Optical Plastic Film

An optical plastic film of the present disclosure according to the first aspect comprises:

a first surface and a second surface that is a surface on a side opposite to the first surface, wherein

the plastic film has an in-plane phase difference of 300 nm or more and 1,450 nm or less, and

in a region within a depth of 20 μm from the first surface in a direction from the first surface to the second surface, an average of an erosion rate is 1.4 μm/g or more.

As used herein, the average of the erosion rate is sometimes referred to as E₀₋₂₀.

An optical plastic film of the present disclosure according to the second aspect is:

the optical plastic film according to the first aspect, wherein

in the region within a depth of 20 μm from the first surface in the direction from the first surface to the second surface, a ratio of variation of the erosion rate to the average of the erosion rate is 0.100 or less.

As used herein, the variation of the erosion rate is sometimes referred to as σ₀₋₂₀/E₀₋₂₀. As used herein, the ratio is sometimes referred to as E₀₋₂₀.

An optical plastic film of the present disclosure according to the third aspect is:

the optical plastic film according to the first or second aspect, wherein

when the in-plane phase difference of the plastic film is defined as Re and the phase difference in the thickness direction is defined as Rth, Re/Rth is 0.15 or less.

### <In-Plane Phase Difference>

An optical plastic film of the present disclosure should have an in-plane phase difference of 300 nm or more and 1,450 nm or less.

The small in-plane phase difference of the plastic film means that the molecular orientation of resin constituting the plastic film is insufficient and/or the thickness of the plastic film is thin. Accordingly, when the plastic film has an in-plane phase difference of less than 300 nm, the pencil hardness cannot be improved.

On the other hand, when the in-plane phase difference of the plastic film exceeds 1,450 nm, the plastic film becomes thick, and thus the image display device cannot be made thinner. In addition, when the in-plane phase difference of the plastic film exceeds 1,450 nm, the polarization state is disturbed when linearly polarized light passes through the plastic film, and rainbow pattern unevenness is easily observed when viewed with the naked eyes. As used herein, the term “rainbow pattern unevenness” is sometimes referred to as “rainbow unevenness”. Further, when the in-plane phase difference of the plastic film exceeds 1,450 nm, a bending habit may remain in the plastic film or the plastic film may break when folded.

The lower limit of the in-plane phase difference of the plastic film is preferably 350 nm or more, more preferably 400 nm or more, still more preferably 450 nm or more, still more preferably 500 nm or more, still more preferably 510 nm or more, still more preferably 520 nm or more, and still more preferably 550 nm or more, and the upper limit is preferably 1,400 nm or less, more preferably 1,200 nm or less, still more preferably 1,000 nm or less, still more preferably 800 nm or less, still more preferably 700 nm or less, and still more preferably 650 nm or less. In order to improve the mechanical strength, the in-plane phase difference of the plastic film is preferably 550 nm or more.

When the thickness of the plastic film is reduced to 10 μm or more and 50 μm or less, Re is preferably 1,400 nm or less.

In the requirements shown herein, multiple options for the upper and lower limits of each numerical value may be indicated. In this case, one of the upper limit options and one of the lower limit options may be combined to provide an embodiment of the numerical range.

In the case of the in-plane phase difference, examples of the embodiment of the numerical range include 300 nm or more and 1,450 nm or less, 350 nm or more and 1,450 nm or less, 400 nm or more and 1,450 nm or less, 450 nm or more and 1,450 nm or less, 500 nm or more and 1,450 nm or less, 510 nm or more and 1,450 nm or less, 520 nm or more and 1,450 nm or less, 550 nm or more and 1,450 nm or less, 300 nm or more and 1,200 nm or less, 350 nm or more and 1,200 nm or less, 400 nm or more and 1,200 nm or less, 450 nm or more and 1,200 nm or less, 500 nm or more and 1,200 nm or less, 510 nm or more and 1,200 nm or less, 520 nm or more and 1,200 nm or less, 550 nm or more and 1,200 nm or less, 300 nm or more and 1,000 nm or less, 350 nm or more and 1,000 nm or less, 400 nm or more and 1,000 nm or less, 450 nm or more and 1,000 nm or less, 500 nm or more and 1,000 nm or less, 510 nm or more and 1,000 nm or less, 520 nm or more and 1,000 nm or less, 550 nm or more and 1,000 nm or less, 300 nm or more and 800 nm or less, 350 nm or more and 800 nm or less, 400 nm or more and 800 nm or less, 450 nm or more and 800 nm or less, 500 nm or more and 800 nm or less, 510 nm or more and 800 nm or less, 520 nm or more and 800 nm or less, 550 nm or more and 800 nm or less, 300 nm or more and 700 nm or less, 350 nm or more and 700 nm or less, 400 nm or more and 700 nm or less, 450 nm or more and 700 nm or less, 500 nm or more and 700 nm or less, 510 nm or more and 700 nm or less, 520 nm or more and 700 nm or less, 550 nm or more and 700 nm or less, 300 nm or more and 650 nm or less, 350 nm or more and 650 nm or less, 400 nm or more and 650 nm or less, 450 nm or more and 650 nm or less, 500 nm or more and 650 nm or less, 510 nm or more and 650 nm or less, 520 nm or more and 650 nm or less, or 550 nm or more and 650 nm or less.

As used herein, various parameters such as in-plane phase difference, E₀₋₂₀, σ₀₋₂₀/E₀₋₂₀, total light transmittance, and haze mean the average of 14 measured values obtained by excluding two of the maximum and the minimum from measured values at 16 points. The above-mentioned various parameters may be measured using the same sample. When the same sample is used, E₀₋₂₀ and σ₀₋₂₀/E₀₋₂₀ are preferably measured after measurements of optical properties such as the in-plane phase difference, the total light transmittance, and haze.

As used herein, as for the 16 measurement points, a 0.5 cm region from the outer edge of the measurement sample is excluded as a margin, and 16 intersection points of lines that are drawn to divide the remaining region into five equal parts in the vertical and horizontal directions are preferably used as the center of measurement. For example, in the case where the measurement sample is a rectangle, it is preferable to perform the measurement by excluding a 0.5 cm region from the outer edge of the rectangle as a margin and using 16 intersection points of dotted lines that divide the remaining region into five equal parts in the vertical and horizontal directions as the center. If the measurement sample is a shape other than a rectangle, such as a circle, an ellipse, a triangle, and a pentagon, it is preferable to draw a rectangle inscribed in these shapes and measure 16 points on the rectangle by the above method.

Examples of the plastic film include the case of a sheet-like shape or the case of a roll-like shape.

In the case of a sheet-like plastic film, the above 16 points should be identified in the sheet-like shape.

Meanwhile, in the case of a roll-like plastic film, a sheet of a predetermined size, such as a length of 100 mm×a width of 100 mm, is cut out, and the above 16 points should be identified in the cut-out sheet shape. The properties of the roll-like plastic film in the flow direction film are roughly the same. Accordingly, if a sheet with a length of 100 mm×width of 100 mm cut out from a arbitrary position A in the width direction satisfies predetermined conditions such as an erosion rate, then at the arbitrary position A, the sheet is simulated such that the every sample in the roll flow direction satisfies the predetermined conditions.

As used herein, various parameters such as in-plane phase difference, E₀₋₂₀, σ₀₋₂₀/E₀₋₂₀, total light transmittance, and haze are measured in an atmosphere with a temperature of 23±5° C. and a humidity of 40% RH or more and 65% RH or less, unless otherwise specified. Before the start of each measurement, the target sample should be exposed to the atmosphere for 30 minutes or more and 60 minutes or less.

As used herein, the in-plane phase difference (Re), phase difference in the thickness direction(Rth) are expressed in the following equations (1) and (2) by using the refractive index nx in the slow-axis direction, which is the direction with the highest refractive index at each measurement point, the refractive index ny in the fast-axis direction, which is the direction orthogonal to the slow-axis direction at each measurement point, the refractive index nz in the thickness direction of the plastic film, and the thickness T [nm] of the plastic film. As used herein, the in-plane phase difference (Re) and phase difference in the thickness direction (Rth) mean values at a wavelength of 550 nm.

In-plane phase difference (Re)=(nx−ny)×T[nm] (1)

Phase difference in thickness direction (Rth)=((nx+ny)/2−nz)×T[nm] (2)

The direction of the slow axis, the in-plane phase difference (Re) and the phase difference in the thickness direction (Rth) may be measured, for example, with the trade name “RETS-100”, manufactured by OTSUKA ELECTRONICS CO., LTD.

In the case of measuring, for instance, the in-plane phase difference (Re) by using the trade name “RETS-100”, manufactured by OTSUKA ELECTRONICS CO., LTD., it is preferable to prepare for the measurement according to the following procedures (A1) to (A4).
(A1) First, to stabilize the light source of RETS-100, leave it on for 60 minutes or more after turning on the light source. Then, select an optical rotational analyzer method and select θ mode (a mode for angular phase difference measurement and Rth calculation). By selecting this θ mode, the stage becomes an inclined rotation stage.
(A2) Then, input the following measurement conditions to the RETS-100.

### (Measurement Conditions)

Measurement range of in-plane phase difference: Optical rotational analyzer method
Measurement spot diameter: ϕ 5 mm
Inclination angle range: 0°
Measurement wavelength range: 400 nm or more and 800 nm or less
Plastic film average refractive index: For example, in the case of a PET film, N=1.617. The plastic film average refractive index N can be calculated based on nx, ny, and nz by using the equation (N=(nx+ny+nz)/3).
Thickness: Thickness separately measured by SEM or an optical microscope
(A3) Then, obtain background data without placing the sample in this instrument. The instrument should be a closed system, and perform this procedure every time the light source is turned on.
(A4) Thereafter, place the sample on a stage in the instrument for measurement.

If the plastic film has thereon a layer or a film that affects the values of the in-plane phase difference and the phase difference in the thickness direction, the in-plane phase difference and the phase difference in the thickness direction of the plastic film may be measured after the layer and film are peeled off. Note that the layer formed by coating usually does not affect the values of the in-plane phase difference and the phase difference in the thickness direction.

Examples of methods of peeling the layer or film that affects the values of the in-plane phase difference and the phase difference in the thickness direction include the following methods.

### <Method of Peeling>

A sample having a 5 cm square or more is immersed in warm water of 80° C. or more and 90° C. or less for 5 minutes. The sample is then taken out from the warm water and left at room temperature for 10 minutes or more. Thereafter, the sample is further immersed in warm water for 5 minutes and taken out from the warm water. A cutter or the like is used to cut a slit in the sample. The cut is then used as a starting point to peel off the layer and film.

In the above method, it is preferable to immerse the sample in warm water while the edges of the sample are attached to a metal frame, etc.

### <Erosion Rate (E₀₋₂₀)>

The optical plastic film of the present disclosure should have an average erosion rate of 1.4 μm/g or more in a region within a depth of 20 μm from the first surface in a direction from the first surface to the second surface.

As used herein, E₀₋₂₀ is measured under the following measurement conditions.

### <Measurement Conditions>

A test solution is prepared by mixing pure water, dispersion, and spherical silica with an average particle size within ±8% of 4.2 μm as a reference at a mass ratio of 968:2:30, and is then put into a container. The test solution in the container is fed to a nozzle. Compressed air is fed into the nozzle to accelerate the test solution within the nozzle, and a predetermined amount of the test solution is jetted perpendicularly onto the first surface of the plastic film through a jet hole at the tip of the nozzle. This causes the spherical silica in the test solution to collide with the plastic film. The cross-sectional shape of the nozzle is 1 mm×1 mm square, and the distance between the jet hole and the plastic film is 4 mm. Meanwhile, the flow rate of the test liquid or the compressed air supplied to the nozzle, the pressure of the compressed air, and the pressure of the test liquid in the nozzle should be predetermined values adjusted by the calibration described below.

After a predetermined amount of the test solution is jetted, the jetting of the test solution is temporarily stopped.

After the jetting of the test solution is temporarily stopped, the cross-sectional profile of the plastic film where the spherical silica particles in the test solution have collided is measured.

One cycle consists of three steps including: a step of jetting a predetermined amount of the test solution from the jet hole; a step of temporarily stopping the jetting of the test solution after the predetermined amount of the test solution is jetted; and a step of measuring the cross-sectional profile after the jetting of the test solution is temporarily stopped. This operation is repeated until the depth of the cross-sectional profile exceeds 20 μm. Then, the erosion rate (μm/g) of the plastic film is calculated for each cycle until the depth of the cross-sectional profile reaches 20 μm. The erosion rate of the plastic film for each cycle until the depth of the cross-sectional profile reaches 20 μm is averaged to calculate the above E₀₋₂₀.

### <Calibration>

The test solution is put into the container. The test solution in the container is fed to the nozzle. Compressed air is fed into the nozzle to accelerate the test solution within the nozzle, and an arbitrary amount of the test solution is jetted perpendicularly onto an acrylic plate with a thickness of 2 mm through a jet hole at the tip of the nozzle. This causes the spherical silica in the test solution to collide with the acrylic plate. The cross-sectional shape of the nozzle is 1 mm×1 mm square, and the distance between the jet hole and the acrylic plate is 4 mm.

After an arbitrary amount of the test solution is jetted, the jetting of the test solution is temporarily stopped. After the jetting of the test solution is temporarily stopped, the cross-sectional profile of the acrylic plate where the spherical silica particles in the test solution have collided is measured.

The erosion rate (μm/g) of the acrylic plate is calculated by dividing the depth (μm) of the cross-sectional profile by the arbitrary amount (g).

If the erosion rate of the acrylic plate is within ±5% of 1.88 (μm/g) as a reference, the test is passed. Meanwhile, the flow rate of the test liquid or the compressed air, the pressure of the compressed air, and the pressure of the test liquid in the nozzle should be adjusted and calibrated so that the erosion rate of the acrylic plate is within the range.

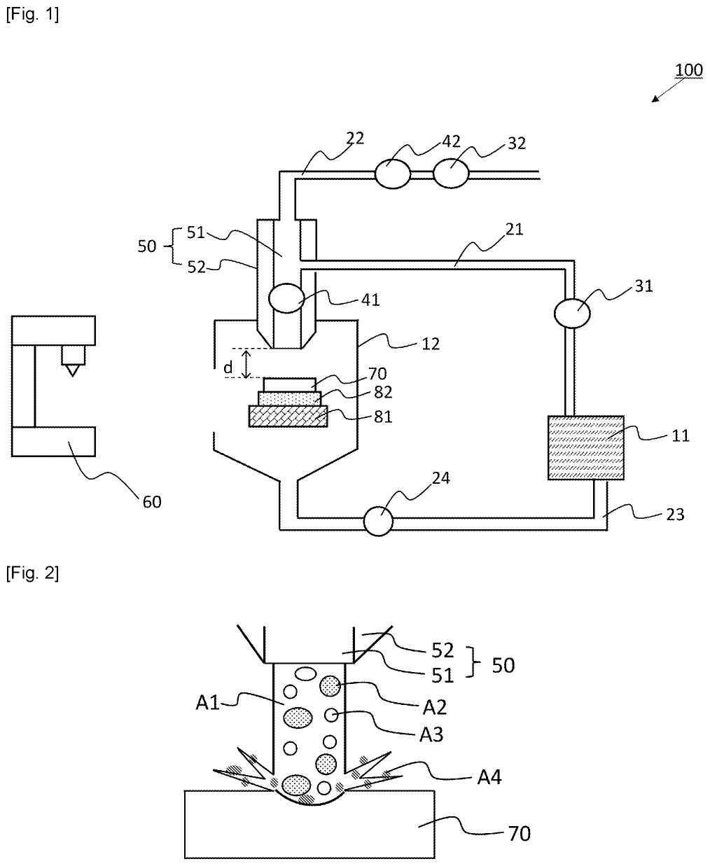

Hereinafter, the measurement conditions of the erosion rate and the technical significance of the erosion rate calculated using the measurement conditions are explained with reference to FIG. 1. For example, an instrument for measuring the erosion rate as shown in FIG. 1 is an MSE testing instrument, product number “MSE-A203”, of Palmeso Co., Ltd.

The erosion rate of the present disclosure is measured under the following conditions. First, a test solution is prepared by mixing pure water, a dispersant, and spherical silica with an average particle size within ±8% of 4.2 μm as a reference at a mass ratio of 968:2:30, and is then put into a container (11). In the container (11), the test solution preferably be stirred.

The dispersant is not particularly limited as long as the spherical silica can be dispersed. Examples of the dispersant include the trade name “DEMOL N” from Wako Pure Chemical Industries, Ltd.

In other words, “average particle size within ±8% of 4.2 μm as a reference” means that the average particle size is 3.864 μm or more and 4.536 μm or less.

In the measurement conditions of erosion rate herein, the “average particle size of spherical silica” is measured as the volume-averaged value d50 in the particle size distribution measurement by laser light diffractometry (the so-called “median diameter”).

In the results of measuring the particle size distribution of the spherical silica, the maximum frequency of the particle size is normalized to 100. At that time, the range of particle size with a frequency of 50 preferably be within ±10% of 4.2 μm as a reference. The phrase “range of particle size with a frequency of 50” is expressed as “X−Y (μm)” while “X is defined as the particle size that has a frequency of 50 and is positioned in a more plus direction than the particle size with a frequency of 100” and “Y is defined as the particle size that has a frequency of 50 and is positioned in a more minus direction than the particle size with a frequency of 100.” Note that as used herein, the “range of particle size with a frequency of 50” is sometimes referred to as the “full width at half-maximum of the particle size distribution”.

Examples of the spherical silica with an average particle size within ±8% of 4.2 μm as a reference is model number “MSE-BS-5-3” designated by Palmeso Co., Ltd. Examples of the spherical silica corresponding the model number “MSE-BS-5-3” designated by Palmeso Co., Ltd. include the product number “BS5-3” of Potters-Ballotini Co., Ltd.

The test solution in the container is fed into a nozzle (51). The test solution may, for example, be sent to the nozzle through piping (21) for the test solution. Between the container (11) and the nozzle (51), a flow meter (31) for measuring the flow rate of the test solution is preferably disposed. The flow rate of the test solution should be a value adjusted by the above-mentioned calibration.

Note that in FIG. 1, the nozzle (51) is located inside a housing (52) that constitutes a jetting section (50).

Compressed air is fed into the nozzle (51). The compressed air is delivered to the nozzle, for example, through a compressed air line (22). The position in the nozzle where the compressed air is fed preferably be upstream of the position where the test solution is fed. The upstream side is the side far from the nozzle's jet hole.

A flow meter (32) for measuring the flow rate of the compressed air and a pressure gauge (42) for measuring the pressure of the compressed air are preferably installed before the compressed air arrives at the nozzle (51). The compressed air may be supplied using, for instance, an air compressor (not shown).

The flow rate and the pressure of the compressed air should each be a value adjusted by the above-mentioned calibration.

When compressed air is delivered into the nozzle (51), the test solution is accelerated while being mixed by the compressed air. The accelerated test solution is then jetted through the jet hole at the tip of the nozzle (51) and impacts perpendicularly against the first surface of a plastic film (70). The plastic film is mainly worn by spherical silica particles in the test solution.

The inside of the nozzle (51) is preferably provided with a pressure gauge (41) for measuring the pressure of the test solution in the nozzle. The pressure gauge (41) is preferably provided downstream of the position where the compressed air is fed and the position where the test solution is fed.

The pressure of the test solution in the nozzle (51) should be a value adjusted by the above-mentioned calibration.

The test solution jetted through the jet hole at the tip of the nozzle (51) is mixed with air and then sprayed. This can lower the impact pressure of spherical silica particles on the plastic film. Thus, the amount of abrasion of the plastic film by one spherical silica particle can be reduced to a small amount. FIG. 2 is a diagram that depicts the state of abrasion of the optical plastic film (70) by using a test solution containing pure water (A1) and spherical silica (A2) as jetted from the jetting section (50). In FIG. 2, reference sign A3 denotes air and reference sign A4 denotes a worn optical plastic film.

In addition, the test solution contains water, which has an excellent cooling effect. This can practically eliminate deformation and alteration of the plastic film as caused by heat at the time of impact. In other words, abnormal abrasion of the plastic film can be virtually eliminated. In addition, the water also plays a role in cleaning the worn plastic film surface and achieving stable abrasion. Further, the water also plays a role in accelerating the spherical silica particles and controlling how the test solution flows.

Furthermore, since a huge number of spherical silica particles collide with the plastic film, the influence of subtle differences in physical properties of individual spherical silica particles can be eliminated.

Moreover, in the measurement conditions of the present disclosure, the flow rate of the test solution supplied to the nozzle, the flow rate of the compressed air supplied to the nozzle, the pressure of the compressed air supplied to the nozzle, and the pressure of the test solution in the nozzle should each be a value adjusted by the above calibration. Also, the cross-sectional shape of the nozzle is specified as a square of 1 mm×1 mm. On top of that, the distance between the jet hole and the plastic film is specified as 4 mm. This can define the factors that affect the amount of abrasion of the plastic film. The distance is denoted by “d” in FIG. 1, and means the vertical distance between the nozzle tip, namely the jet hole, and the plastic film.

From the above, it can be said that the measurement conditions of the present disclosure are those that enable the formation of statistically stable abrasion marks on the plastic film.

The plastic film (70) may be attached to a sample mount (81) of a measurement instrument (100). It is preferable to attach the plastic film (70) to the sample mount (81) through a support (82) such as a stainless steel plate.

The test solution jetted onto the plastic film (70) preferably be collected in a receptor (12) and returned to the container (11) through return piping (23). Between the receptor (12) and the return piping (23), a return pump (24) is preferably disposed.

The measurement conditions of the present disclosure require that the jetting of the test solution is temporarily stopped after the jetting of a predetermined amount of the test solution, and that the cross-sectional profile of the plastic film where the spherical silica particles in the test solution collide is measured after the jetting of the test solution is temporarily stopped.

The cross-sectional profile means the cross-sectional shape of the plastic film worn by the test solution. The plastic film is mainly worn by spherical silica particles in the test solution.

The cross-sectional profile may be measured by the cross-sectional profile acquisition unit (60) such as a stylus-type surface profilometer or a laser interferometry-type surface profilometer. The cross-sectional profile acquisition unit (60) is usually located at a position away from the plastic film (70) when the test solution is jetted. For this reason, it is preferable that at least one of the plastic film (70) or the cross-sectional profile acquisition unit (60) is movable.

Palmeso Co., Ltd.'s MSE tester, product number “MSE-A203”, uses a stylus method for measuring a cross-sectional profile.

Further, under the measurement conditions of the present disclosure, one cycle consists of three steps: a step of jetting a predetermined amount of test solution from the jet hole; a step of temporarily stopping the jetting of the test solution after the predetermined amount of the test solution is jetted; and a step of measuring a cross-sectional profile after the jetting of the test solution is temporarily stopped. This operation is repeated until the depth of the cross-sectional profile exceeds 20 μm.

This operation is executed to measure the erosion rate of the plastic film at each cycle, and further calculate variation of the erosion rate of the plastic film.

The above cycle may be continued after the depth of the cross-sectional profile exceeds 20 μm, but it is preferable to terminate the cycle when the depth of the cross-sectional profile exceeds 20 μm. The reason why the measurement is limited to the “depth of 20 μm from the first surface of the plastic film” is that the physical properties of the plastic film tend to fluctuate at or near the surface, while they tend to be more stable as the site gets into a deeper portion.

As used herein, the erosion rate at each cycle can be calculated by dividing the depth of the cross-sectional profile having progressed in each cycle (μm) by the amount (g) of the test solution jetted in each cycle. The depth (μm) of the cross-sectional profile in each cycle is the depth of the deepest position of the cross-sectional profile at each cycle.

The amount of the test solution jetted in each cycle is, in principle, a “fixed quantity”, but it may vary slightly from cycle to cycle.

The amount of the test solution jetted in each cycle is not particularly limited, but the lower limit is preferably 0.5 g or more and more preferably 1.0 g or more, and the upper limit is preferably 3.0 g or less and more preferably 2.0 g or less.

Under the measurement conditions of the present disclosure, the erosion rate (μm/g) is calculated for each cycle until the depth of the cross-sectional profile reaches 20 μm. The erosion rate at each cycle until the depth of the cross-sectional profile reaches 20 μm is then averaged to calculate E₀₋₂₀.

This cycle is repeated until the depth of the cross-sectional profile exceeds 20 μm. Here, the data obtained at the cycle with a cross-sectional profile depth of more than 20 μm is excluded from the date for calculating E₀₋₂₀.

In general, the softer the plastic film is, the easier it is to scratch, and the harder the film is, the harder it is to scratch. The present inventors considered using the values obtained from evaluations using a picodentor in the depth direction, including, for instance, Martens hardness, indentation hardness, and elastic recovery work, as an index of pencil hardness. Unfortunately, the above-described parameters such as Martens hardness, indentation hardness, and elastic recovery work were sometimes unable to be used as an index of pencil hardness.

In addition, the plastic film when stretched tends to have increased strength. Specifically, uniaxially stretched plastic films tend to have better pencil hardness than unstretched plastic films; and biaxially stretched plastic films tend to have better pencil hardness than the uniaxially stretched plastic films. However, there were cases where pencil hardness was insufficient even for the biaxially stretched plastic films.

The present inventors then examined the erosion rate as an index of pencil hardness of the plastic film. As mentioned above, plastic films are more easily scratched if they are soft and less easily scratched if they are hard. Therefore, it is considered that a smaller erosion rate can correspond to better pencil hardness. However, the present inventors have, instead, found that by increasing the erosion rate (E₀₋₂₀) to 1.4 μm/g or more, the plastic film can have favorable pencil hardness. The present inventors have also found that the erosion rate of the plastic film tends to be larger for biaxially stretched plastic films than for uniaxially stretched plastic films, and that the erosion rate can be used to determine whether the pencil hardness of biaxially stretched plastic film is favorable or not.

The reason why the erosion rate of the plastic film correlates with pencil hardness may be as follows.

As described above, under the measurement conditions of the present disclosure, the test solution containing water and spherical silica is mixed with air and sprayed in misty. This can lower the impact pressure of spherical silica particles on the plastic film. Accordingly, in the case of a soft plastic film, the stresses caused by the spherical silica colliding with the plastic film are easily dispersed. This seems to cause the plastic film to be less prone to abrasion, resulting in a low erosion rate. By contrast, in the case of a hard plastic film, the stresses caused by the spherical silica colliding with the plastic film are not easily dispersed. This seems to cause the plastic film to be more prone to abrasion, resulting in a high erosion rate.

Biaxially stretched plastic films have different erosion rates. This seems to be caused by the difference in the degree of elongation of molecular chains and the difference in the degree of molecular orientation. For example, in biaxially stretched plastic films, the molecules are, in principle, stretched in-plane. However, there may be some molecules that are not sufficiently stretched locally in the plane. Thus, it is expected that the biaxially stretched plastic film becomes locally softer and the erosion rate decreases as the percentage of molecules that are not sufficiently stretched locally in the plane increases.

In addition, even biaxially stretched plastic films with comparable in-plane phase differences are considered to exhibit different erosion rates due to differences in local molecular orientation. By contrast, even biaxially stretched plastic films with comparable erosion rates may exhibit different in-plane phase differences due to differences in rates between the stretching ratio in the flow direction and stretching ratio in the width direction.

In the present disclosure, E₀₋₂₀ should be 1.4 μm/g or more. When E₀₋₂₀ is less than 1.4 μm/g, the plastic film does not have favorable pencil hardness.

To make pencil hardness F or higher readily, E₀₋₂₀ is preferably 1.5 μm/g or more, more preferably 1.6 μm/g or more, still more preferably 1.8 μm/g or more, still more preferably 1.9 μm/g or more, and still more preferably 2.0 μm/g or more.

As described above, it is expected that the erosion rate decreases as the percentage of molecules that are not sufficiently stretched locally in the plane increases. In other words, it is expected that the percentage of molecules that are not sufficiently stretched locally in the plane decreases when the erosion rate is high. Thus, it can be made easier to suppress the occurrence of wrinkles in the plastic film under a high temperature environment by setting E₀₋₂₀ to 1.4 μm/g or more.

The E₀₋₂₀ is preferably 3.0 μm/g or less, more preferably 2.5 μm/g or less, and still more preferably 2.2 μm/g or less in order to make the plastic film less susceptible to cracking.

Even if the value of E₀₋₂₀ is the same, the plastic film may have different characteristics when the in-plane phase difference or the like is different. For example, even if the value of E₀₋₂₀ is the same, when the in-plane phase difference exceeds 1,450 nm, a bending habit may remain in the plastic film or the plastic film may break when folded.

For the plastic film in which E₀₋₂₀ is less than 1.4 μm/g, even if a cured film having a high hardness is formed on the plastic film, the pencil hardness of the cured film may not be improved due to insufficient hardness of the plastic film.

Examples of the embodiment of a preferable numerical range of E₀₋₂₀ include 1.4 μm/g or more and 3.0 μm/g or less, 1.4 μm/g or more and 2.5 μm/g or less, 1.4 μm/g or more and 2.2 μm/g or less, 1.5 μm/g or more and 3.0 μm/g or less, 1.5 μm/g or more and 2.5 μm/g or less, 1.5 μm/g or more and 2.2 μm/g or less, 1.6 μm/g or more and 3.0 μm/g or less, 1.6 μm/g or more and 2.5 μm/g or less, 1.6 μm/g or more and 2.2 μm/g or less, 1.8 μm/g or more and 3.0 μm/g or less, 1.8 μm/g or more and 2.5 μm/g or less, 1.8 μm/g or more and 2.2 μm/g or less, 1.9 μm/g or more and 3.0 μm/g or less, 1.9 μm/g or more and 2.5 μm/g or less, 1.9 μm/g or more and 2.2 μm/g or less, 2.0 μm/g or more and 3.0 μm/g or less, 2.0 μm/g or more and 2.5 μm/g or less, or 2.0 μm/g or more and 2.2 μm/g or less.

The value of E₀₋₂₀ described above is a value measured from the first surface side. In the optical plastic film of the present disclosure, an erosion rate measured from the second surface side is also preferably the above-described value. Specifically, in the optical plastic film of the present disclosure, an erosion rate is preferably 1.4 μm/g or more in the region within a depth of 20 μm from the first surface in the direction to the second surface. For normal plastic films, the erosion rate measured from the first surface side and the erosion rate measured from the second surface side are identical.

Before the erosion rate described above is measured, the above-described calibration should be performed.

For example, the calibration can be conducted as follows.

### <Calibration>

The test solution is put into the container. The test solution in the container is fed to the nozzle. Compressed air is fed into the nozzle to accelerate the test solution within the nozzle, and an arbitrary amount of the test solution is jetted perpendicularly onto an acrylic plate with a thickness of 2 mm through a jet hole at the tip of the nozzle. This causes the spherical silica in the test solution to collide with the acrylic plate. The cross-sectional shape of the nozzle is 1 mm×1 mm square, and the distance between the jet hole and the acrylic plate is 4 mm.

After an arbitrary amount of the test solution is jetted, the jetting of the test solution is temporarily stopped. After the jetting of the test solution is temporarily stopped, the cross-sectional profile of the acrylic plate where the spherical silica particles in the test solution have collided is measured.

The erosion rate (μm/g) of the acrylic plate is calculated by dividing the depth (μm) of the cross-sectional profile by the arbitrary amount (g).

If the erosion rate of the acrylic plate is within ±5% of 1.88 (μm/g) as a reference, the test is passed. Meanwhile, the flow rate of the test liquid or the compressed air, the pressure of the compressed air, and the pressure of the test liquid in the nozzle should be adjusted and calibrated so that the erosion rate of the acrylic plate is within the range.

The test solution used in the calibration should be the same as the test solution used in the measurement conditions to be implemented later.

The measurement instrument used in the calibration should be the same as the test solution used in the measurement conditions to be implemented later.

The difference between the calibration and the measurement conditions to be implemented later is, for example, the use of a 2 mm-thick acrylic plate as a standard sample in the calibration, whereas a plastic film is used as a sample in the measurement conditions.

The standard sample, an acrylic plate of 2-mm thickness, is preferably a polymethyl methacrylate plate (PMMA plate). The acrylic sheet with a thickness of 2 mm as a standard sample preferably has an AcE of 1.786 μm/g or more and 1.974 μm/g or less, when AcE is defined as the average erosion rate of acrylic sheet measured under the following measurement conditions A. Here, examples of the spherical silica under the following measurement conditions A is model number “MSE-BS-5-3” designated by Palmeso Co., Ltd. Examples of the spherical silica corresponding the model number “MSE-BS-5-3” designated by Palmeso Co., Ltd. include the product number “BS5-3” of Potters-Ballotini Co., Ltd.

### <Measurement Conditions A>

A test solution is prepared by mixing pure water, a dispersant, and spherical silica with an average particle size within ±8% of 4.2 μm at a mass ratio of 968:2:30, and is then put into a container. The test solution in the container is fed to a nozzle. Compressed air is fed into the nozzle to accelerate the test solution within the nozzle, and a predetermined amount of the test solution is jetted perpendicularly onto the acrylic plate through a jet hole at the tip of the nozzle. This causes the spherical silica in the test solution to collide with the acrylic plate. The cross-sectional shape of the nozzle is 1 mm×1 mm square, and the distance between the jet hole and the acrylic plate is 4 mm. Meanwhile, the flow rate of the test liquid or the compressed air supplied to the nozzle, the pressure of the compressed air, and the pressure of the test liquid in the nozzle is provided such that the flow rate of the test liquid is 100 ml/min or more and 150 ml/min or less, the flow rate of the compressed air is 4.96 L/min or more and 7.44 L/min or less, the pressure of the compressed air is 0.184 MPa or more and 0.277 MPa or less, and the pressure of the test liquid in the nozzle is 0.169 MPa or more and 0.254 MPa or less.

After 4 g of the test solution is jetted, the jetting of the test solution is temporarily stopped.

After the jetting of the test solution is temporarily stopped, the cross-sectional profile of the acrylic plate where the spherical silica particles in the test solution have collided is measured.

The erosion rate AcE (unit: “μm/g”) of the acrylic plate is calculated by dividing the depth (μm) of the cross-sectional profile by the amount of the test solution jetted (4 g).

If the erosion rate of the acrylic plate during calibration is within ±5% of 1.88 (μm/g) as a reference, the test is passed. Meanwhile, the flow rate of the test liquid or the compressed air, the pressure of the compressed air, and the pressure of the test liquid in the nozzle should be adjusted for implementation so that the erosion rate of the acrylic plate is within the range.

The wording “the erosion rate is within ±5% of 1.88 (μm/g) as a reference” means, in other words, that the erosion rate is 1.786 (μm/g) or more and 1.974 (μm/g) or less.

<Ratio of Variation of Erosion Rate to Average of Erosion Rate (σ₀₋₂₀/E₀₋₂₀)>

In the plastic film, in a region within a depth of 20 μm from the first surface in a direction from the first surface to the second surface, a ratio of variation of the erosion rate to the average of the erosion rate is preferably 0.100 or less.

As used herein, σ₀₋₂₀, the variation of the erosion rate can be calculated from the erosion rate for each cycle until the depth of the cross-sectional profile reaches 20 μm under the above measurement conditions.

Here, σ₀₋₂₀/E₀₋₂₀ indicates the coefficient of variation of the erosion rate, and a small value of σ₀₋₂₀/E₀₋₂₀ means that the erosion rate is less likely to vary in the thickness direction of the plastic film. By setting σ₀₋₂₀/E₀₋₂₀ to 0.100 or less, the erosion rate in the thickness direction is stabilized and better pencil hardness can be easily obtained.

The upper limit of σ₀₋₂₀/E₀₋₂₀ is more preferably 0.080 or less, still more preferably 0.070 or less, still more preferably 0.060 or less, and still more preferably 0.055 or less.

The lower limit of σ₀₋₂₀/E₀₋₂₀ is not particularly limited, but is usually more than 0, preferably 0.020 or more, and more preferably 0.035 or more. In addition, when the value of σ₀₋₂₀/E₀₋₂₀ is low, the plastic film may stretch weakly. The plastic film with weak stretching tends to have poor solvent resistance, break easily, and be less stable to heat and moisture. Thus, σ₀₋₂₀/E₀₋₂₀ is preferably 0.020 or more.

Examples of the embodiment of the preferred numerical range of σ₀₋₂₀/E₀₋₂₀ include more than 0 and 0.100 or less, more than 0 and 0.080 or less, more than 0 and 0.070 or less, more than 0 and 0.060 or less, more than 0 and 0.055 or less, 0.020 or more and 0.100 or less, 0.020 or more and 0.080 or less, 0.020 or more and 0.070 or less, 0.020 or more and 0.060 or less, 0.020 or more and 0.055 or less, 0.035 or more and 0.100 or less, 0.035 or more and 0.080 or less, 0.035 or more and 0.070 or less, 0.035 or more and 0.060 or less, or 0.035 or more and 0.055 or less.

The value of σ₀₋₂₀/E₀₋₂₀ described above is a value measured from the first surface side. In the optical plastic film of the present disclosure, σ₀₋₂₀/E₀₋₂₀ measured from the second surface side is preferably the above-described value. Specifically, in the optical plastic film of the present disclosure, σ₀₋₂₀/E0-20 is preferably 0.100 or less in the region within a depth of 20 μm from the first surface in the direction to the second surface.

In the optical plastic film of the present disclosure, Re/Rth is preferably 0.15 or less when the in-plane phase difference of the plastic film is defined as Re (nm) and the phase difference in the thickness direction of the plastic film as Rth (nm). The smaller the ratio (Re/Rth) of the in-plane phase difference (Re)/the phase difference in the thickness direction (Rth), the closer the degree of stretching of the optical plastic film becomes even biaxiality. Thus, by setting Re/Rth to 0.15 or less, it may be made easier to improve the mechanical strength of the optical plastic film.

The Re/Rth is more preferably 0.13 or less, and still more preferably 0.10 or less. The lower limit of the ratio is preferably 0.005 or more, more preferably 0.01 or more, and still more preferably 0.015 or more. When the plastic film is weakly stretched, the plastic film can be easily prevented from becoming brittle by setting the ratio to 0.005 or more. When the plastic film is strongly stretched, it can be made easier to reduce Re by setting the ratio to 0.005 or more.

The Re/Rth of a perfectly uniaxially stretched plastic film is 2.0. A general-purpose uniaxially stretched plastic film is also slightly stretched in the flow direction. Therefore, the Re/Rth of general-purpose uniaxially stretched plastic film is around 1.0.

Examples of the embodiment of the preferred numerical range of Re/Rth include 0.005 or more and 0.15 or less, 0.005 or more and 0.13 or less, 0.005 or more and 0.10 or less, 0.01 or more and 0.15 or less, 0.01 or more and 0.13 or less, 0.01 or more and 0.10 or less, 0.015 or more and 0.15 or less, 0.015 or more and 0.13 or less, or 0.015 or more and 0.10 or less.

In the optical plastic film of the present disclosure, the phase difference in the thickness direction (Rth) is preferably 2,000 nm or more, more preferably 4,000 nm or more, and still more preferably 5,000 nm or more.

By setting Rth to 2,000 nm or more, it is easier to suppress blackout when viewed from an oblique direction through polarized sunglasses. Blackout is a phenomenon in which the entire screen appears black and the image is not visible. In addition, by setting Re to 300 nm or more and 1,450 nm or less and Rth to 2,000 nm or more, the degree of stretching of the optical plastic film can be brought closer to an even biaxial property, and it may be made easier to improve the mechanical strength of the optical plastic film.

In order to make the Rth of the optical plastic film in the above range, it is preferable to increase the stretching ratio in the flow and width directions. By increasing the stretching ratio in the flow and width directions, the refractive index nz in the thickness direction of the biaxially stretched plastic film becomes smaller, making it easier to increase the Rth.

The Rth is preferably 10,000 nm or less, more preferably 8,000 nm or less, and still more preferably 7,000 nm or less to make the plastic film thinner.

Examples of the embodiment of the preferred numerical range of Rth include 2,000 nm or more and 10,000 nm or less, 2,000 nm or more and 8,000 nm or less, 2,000 nm or more and 7,000 nm or less, 4,000 nm or more and 10,000 nm or less, 4,000 nm or more and 8,000 nm or less, 4000 nm or more and 7,000 nm or less, 5,000 nm or more and 10,000 nm or less, 5,000 nm or more and 8,000 nm or less, or 5,000 nm or more and 7,000 nm or less.

### <Plastic Film>

Examples of the lamination structure of the plastic film include a monolayer structure or a multilayer structure.

The plastic film of the present disclosure should have the average in-plane phase difference and erosion rate in the ranges described above. In order to keep the in-plane phase difference of the plastic film in the above range, it is preferable to make the stretching in the longitudinal direction (flow direction) and the stretching in the horizontal direction (width direction) equally close to each other. In order to keep the erosion rate of plastic film within the above range, it is desirable to stretch the molecules evenly within the plane of the plastic film. Accordingly, controlling the stretching is crucial to bring the average in-plane phase difference and erosion rate of the plastic film to the above-mentioned range. Stretching can be controlled even with plastic films having a multilayer structure, but for easier control of stretching, it is preferable that the lamination structure of the plastic film be a monolayer structure

Examples of the resin component constituting the plastic film include polyester, triacetyl cellulose (TAC), cellulose diacetate, cellulose acetate butyrate, polyamide, polyimide, polyethersulfone, polysulfone, polypropylene, polymethylpentene, poly(vinyl chloride), poly(vinyl acetal), poly(ether ketone), poly(methyl methacrylate), polycarbonate, polyurethane, or amorphous olefin (Cyclo-Olefin-Polymer: COP). Among them, polyester is preferred because it is easy to obtain good mechanical strength. In other words, the optical plastic film is preferably a polyester film.

Examples of the polyester constituting the polyester film include polyethylene terephthalate (PET), polyethylene naphthalate (PEN), or polybutylene terephthalate (PBT). Among them, PET is preferred because of its low intrinsic birefringence and low in-plane phase difference.

The plastic film optionally contains additives such as absorbents that absorb special wavelengths such as a UV absorber, light stabilizers, antioxidants, antistatic agents, flame retardants, anti-gelling agents, dyes, pigments, refractive index adjusters, cross-linking agents, blocking prevention agents, organic particles, inorganic particles and/or surfactants.

The lower limit of the thickness of the plastic film is preferably 21 μm or more, more preferably 25 μm or more, and still more preferably 30 μm or more, and the upper limit is preferably 80 μm or less, more preferably 60 μm or less, still more preferably 55 μm or less, and still more preferably 50 μm or less. In order to make the film thinner, the thickness of the plastic film is preferably 50 μm or less.

By setting the thickness to 10 μm or more, it can be made easier to improve the mechanical strength. In addition, by setting the thickness to 80 μm or less, it can be made easier to reduce the in-plane phase difference.

Examples of the embodiment of the preferred numerical range of the thickness of the plastic film include 21 μm or more and 80 μm or less, 21 μm or more and 60 μm or less, 21 μm or more and 55 μm or less, 21 μm or more and 50 μm or less, 25 μm or more and 80 μm or less, 25 μm or more and 60 μm or less, 25 μm or more and 55 μm or less, 25 μm or more and 50 μm or less, 30 μm or more and 80 μm or less, 30 μm or more and 60 μm or less, 30 μm or more and 55 μm or less, or 30 μm or more and 50 μm or less.

The optical plastic film has a JIS K7136:2000 haze of preferably 3.0% or less, more preferably 2.0% or less, still more preferably 1.5% or less, and still further preferably 1.0% or less.

The optical plastic film has a JIS K7361-1:1997 total light transmittance of preferably 80% or more, more preferably 85% or more, and still more preferably 90% or more.

The plastic film is preferably a stretched plastic film and more preferably a stretched polyester film to improve the mechanical strength. Further, it is more preferable that the stretched polyester film has a monolayer structure of polyester resin layer.

The stretched plastic film may be obtained by stretching a resin layer containing components that constitute the plastic film. Examples of the stretching technique include biaxial stretching (e.g., sequential or simultaneous biaxial stretching) or uniaxial stretching (e.g., longitudinal uniaxial stretching). Among them, biaxial stretching is preferred because it is easier to lower the in-plane phase difference and to increase the mechanical strength. In other words, the stretched plastic film is preferably a biaxially stretched plastic film. Among the biaxially stretched plastic films, a biaxially stretched polyester film is preferred, and a biaxially stretched polyethylene terephthalate film is more preferred.

### —Sequential Biaxial Stretching—

In sequential biaxial stretching, a casting film is stretched in the flow direction followed by stretching in the width direction of the film.

The stretching in the flow direction is usually implemented by varying the peripheral speed of a pair of the stretching rolls. The stretching in the flow direction may be implemented in one step or in multiple steps using multiple pairs of stretching rolls. In order to suppress excessive variation in optical properties such as the in-plane phase difference, it is preferable to have multiple nip rolls in close proximity to the stretching rolls. The stretching ratio in the flow direction is usually 2 times or more and 15 times or less, preferably 2 times or more and 7 times or less, more preferably 3 times or more and 5 times or less, and still more preferably 3 times or more and 4 times or less in order to suppress excessive variation in optical properties such as the in-plane phase difference.

The stretching temperature is preferably at the glass transition temperature or more of the resin and at the glass transition temperature+100° C. or less to prevent excessive variation in physical properties such as the in-plane phase difference. For PET, preferred is 70° C. or more and 120° C. or less, more preferred is 80° C. or more and 110° C. or less, and still more preferred is 95° C. or more and 110° C. or less. The stretching temperature means the temperature setting of the instrument. Even if the temperature setting of the instrument is set to the above range, it takes time for the temperature to stabilize. Therefore, it is preferable to produce the plastic film after the temperature is set in the above range and the temperature is also stabilized. In this specification, the temperature setting of the instrument is described in several places. It is preferable to produce the plastic film after the temperature is stabilized, as well as the temperature settings at other sections, as described above.

With respect to the stretching temperature, the temperature of the film may be rapidly increased to shorten the section stretched at low temperatures. This tends to make smaller the average of the in-plane phase difference. Meanwhile, the temperature of the film may be slowly increased to make the section stretched at low temperatures longer. This increases orientation and tends to make larger the average of the in-plane phase difference.

Further in the stretching in the flow direction, the erosion rate tends to decrease as the stretching time is shortened and to increase as the stretching time is extended. The reason for this is thought to be that a short stretching time makes it difficult for the molecules to be stretched evenly in the plane of the plastic film, while a long stretching time makes it easier for the molecules to be stretched evenly in the plane of the plastic film. In other words, to obtain E₀₋₂₀ of 1.4 μm/g or more, it is desirable to increase the stretching time. Further, it is easier to achieve an E₀₋₂₀ of 1.4 μm/g or more by increasing the stretching time while suitably increasing the stretching ratio to the extent that the physical properties do not vary.

The film stretched in the flow direction may be given functions such as better lubricity, better adhesiveness, and antistatic properties by in-line coating or offline coating. Also, surface treatment such as corona treatment, flame treatment, or plasma treatment may be optionally applied prior to the in-line coating or offline coating.

The layer formed by in-line coating or offline coating is herein not counted as the number of layers constituting the polyester film.

The stretching in the width direction is usually performed using the tenter method, in which both ends of the film are gripped with clips and the film is stretched in the width direction while being conveyed. The stretching ratio in the width direction is usually 2 times or more and 15 times or less, and preferably 2 times or more and 7 times or less, more preferably 3 times or more and 6 times or less, and still more preferably 4 times or more and 5 times or less in order to suppress excessive variation in physical properties such as the in-plane phase difference. In addition, it is preferable that the widthwise stretching ratio is higher than the longitudinal stretching ratio.

The stretching temperature is preferably at the glass transition temperature or more of the resin and at the glass transition temperature+110° C. or less. The temperature preferably increase from upstream to downstream. The stretching temperature means the temperature setting of the instrument. The upstream side is the side near the point where stretching in the width direction begins, while the downstream side is the side near the point where stretching in the width direction ends. Specifically, when the stretching section in the width direction is divided into two parts based on the length, the difference between the upstream and downstream temperatures is preferably 20° C. or more, more preferably 30° C. or more, still more preferably 35° C. or more, and still more preferably 40° C. or more. In addition, for PET, the stretching temperature at the first step is preferably 80° C. or more and 120° C. or less, more preferably 90° C. or more and 110° C. or less, and still more preferably 95° C. or more and 105° C. or less. As mentioned above, by dividing the stretching section in the width direction into two parts and providing a difference in stretching temperature between the first and second stages, the surface temperature of the film during the first stage of stretching and the surface temperature of the film during the second stage of stretching can be controlled at different temperatures. This prevents orientation and oriented crystallization from progressing too far in each stretching stage, and prevents the plastic film from becoming brittle, thereby making it easier to improve pencil hardness.

The sequentially biaxially stretched film as so obtained preferably be heat-treated at the stretching temperature or more and less than the melting point in a tenter in order to provide flatness and dimensional stability. The heat treatment temperature means the temperature setting of the instrument. Specifically, for PET, heat fixation is performed in the range preferably 140° C. or more and 240° C. or less and more preferably 200° C. or more and 250° C. or less. In addition, in order to suppress excessive variation in physical properties such as the in-plane phase difference, it is preferable to additionally perform stretching of 1% or more and 10% or less in the first half of heat treatment.

The plastic film is heat-treated, slowly cooled to room temperature, and then rolled up. In addition, the plastic film is optionally subjected to relaxation or other treatment used in combination with heat treatment or slow cooling. The relaxation rate during heat treatment is preferably 0.5% or more and 5% or less, more preferably 0.5% or more and 3% or less, still more preferably 0.8% or more and 2.5% or less, and still more preferably 1% or more and 2% or less to suppress excessive variation in physical properties such as the in-plane phase difference. In addition, the relaxation rate during slow cooling is preferably 0.5% or more and 3% or less, more preferably 0.5% or more and 2% or less, still more preferably 0.5% or more and 1.5% or less, and still more preferably 0.5% or more and 1.0% or less to suppress excessive variation in physical properties such as the in-plane phase difference. The temperature during slow cooling is preferably 80° C. or more and 140° C. or less, more preferably 90° C. or more and 130° C. or less, and still more preferably 100° C. or more and 130° C. or less, and still more preferably 100° C. or more and 120° C. or less to improve the flatness. The temperature during slow cooling means the temperature setting of the instrument.

The conveying speed in the production of stretched plastic film is generally 100 m/s or more and 300 m/s or less.

### —Simultaneous Biaxial Stretching—

In simultaneous biaxial stretching, a casting film is guided to a simultaneous biaxial tenter, where it is conveyed while clipped at both ends and stretched simultaneously and/or stepwise in the flow and width directions. Examples of the simultaneous biaxial stretching machine include a pantograph type, screw type, drive motor type, or linear motor type machine. Here, the stretching ratio can be changed optionally. Preferred is a drive motor type or linear motor type machine that can perform the relaxation process at any location.

The magnification of simultaneous biaxial stretching is usually 6 times or more and 50 times or less as the area ratio. The area ratio is preferably 8 times or more and 30 times or less, more preferably 9 times or more and 25 times or less, still more preferably 9 times or more and 20 times or less, and still more preferably 10 times or more and 15 times or less, in order to suppress excessive variation in physical properties such as the in-plane phase difference. In simultaneous biaxial stretching, it is preferable to adjust the area ratio within the above range while the stretching ratio in the flow and width directions is 2 times or more and 15 times or less.

In addition, in the case of simultaneous biaxial stretching, it is preferable that the stretching ratios in the flow and width directions are almost the same and that the stretching speed in the flow and width directions is almost the same in order to suppress the in-plane orientation difference.

The stretching temperature for simultaneous biaxial stretching is preferably at the glass transition temperature or more of the resin and at the glass transition temperature+120° C. or less to prevent excessive variation in physical properties such as the in-plane phase difference. For PET, preferred is from 80° C. or more and 160° C. or less, more preferred is from 90° C. or more and 150° C. or less, and still more preferred is from 100° C. or more and 140° C. or less. The stretching temperature means the temperature setting of the instrument.

The simultaneously biaxially stretched film preferably is subsequently heat-treated at the stretching temperature or more and less than the melting point in a heat fixing chamber in a tenter in order to provide flatness and dimensional stability. The temperature of the heat treatment means the temperature setting of the instrument. The heat treatment conditions described above are the same as those after the sequential biaxial stretching.

### <Application>

The optical plastic film of the present disclosure can be suitably used as a plastic film included in an image display device. In particular, it can be suitably used as a plastic film included in an image display device with touch panel functions.

The optical plastic film of the present disclosure can be suitably used as a plastic film disposed on the light-emitting surface side of display element in the image display device. At that time, it is preferable to have a polarizer between the display element and the optical plastic film of the present disclosure.

Examples of the plastic film for the image display device include a plastic film used as a base material for various functional films (e.g., a polarizer protection film, a surface protection film, an anti-glare film, an antireflection film, and a conductive film that constitutes a touch panel).

The optical plastic film of the present disclosure can also be used as a member in the production of functional films. Example of the member include base materials for transfer sheets to which functional layers are transferred. In the production process of functional films, examples of the member include base materials used to protect or reinforce the functional films

### Optical Laminate

The optical plastic film of the present disclosure may be further formed with functional layers such as a protective layer, an antireflection layer, a hard coating layer, an anti-glare layer, a phase difference layer, an adhesive layer, a transparent conductive layer, an antistatic layer, and an antifouling layer to form an optical laminate.

The functional layer of the optical laminate preferably includes an antireflection layer. Preferably, the antireflection layer is disposed on the topmost surface on the side of the plastic film with the functional layer.

Having an antireflection layer as a functional layer of the optical laminate makes it easier to suppress rainbow unevenness.

It is more preferable for the functional layer to include a hard coating layer and an antireflection layer. When the functional layer includes a hard coating layer and an antireflection layer, the hard coating layer and the antireflection layer are preferably arranged in this order on the optical plastic film.

The hard coating layer and the antireflection layer can be applied to general-purpose products. The hard coating layer may be further provided with functions such as antiglare, antistatic, and absorption of specific wavelengths such as ultraviolet rays.

The overall thickness of the optical laminate is preferably 100 μm or less and more preferably 60 μm or less in order to maintain the mechanical properties and to suppress excessive variations in optical and physical properties. Preferably, in the optical laminate, the balance between the thickness of the plastic film and the thickness of the functional layer is 10:4 to 10:0.5.

### Polarization Plate

The polarization plate of the present disclosure is a polarization plate comprising: a polarizer; first transparent protective plate disposed on one side of the polarizer; and a second transparent protective plate disposed on the other side of the polarizer, wherein at least one selected from the group consisting of the first transparent protective plate and the second transparent protective plate is the above-described optical plastic film of the present disclosure.

The polarization plate is used to provide antireflective properties by combining, for instance, the polarization plate and a λ/4 phase difference plate. In this case, the λ/4 phase difference plate is disposed on the display element of the image display device, and the polarization plate is disposed on the viewer's side of the display device relative to the λ/4 phase difference plate.

In the case of using the polarization plate for a liquid crystal display device, the polarization plate is used to provide a liquid crystal shutter function. In this case, the liquid crystal display device is arranged in the following order from the backlight side: a lower polarization plate, a liquid crystal display element, and an upper polarization plate. Here, the absorption axis of polarizer of the lower polarization plate and the absorption axis of polarizer of the upper polarization plate are arranged orthogonally. In the configuration of the liquid crystal display device, it is preferable to use the polarization plate in the present disclosure as the upper polarization plate.

### <Transparent Protective Plate>

The polarization plate of the present disclosure includes the above-described optical plastic film of the present disclosure used as at least one of the first transparent protective plate or the second transparent protective plate. A preferred embodiment is that the first and second transparent protective plates are each an optical plastic film of the present disclosure as described above.

In the case where one of the first transparent protective plate or the second transparent protective plate is an optical plastic film of the present disclosure described above, the other transparent protective plate is not particularly limited, but an optically isotropic transparent protective plate is preferred. The optical isotropy refers to an in-plane phase difference of 20 nm or less, preferably 10 nm or less, and more preferably 5 nm or less. Examples of the transparent base material with optical isotropy include acrylic film, triacetyl cellulose film, a polycarbonate film, and amorphous olefin film.

When the polarization plate of the present disclosure is used as a polarization plate to be disposed on the light emitting surface side of the display element, it is preferable that the transparent protective plate on the light emitting surface side of the polarizer be the optical plastic film of the present disclosure. On the other hand, when the polarization plate of the present disclosure is used as a polarization plate to be disposed on the opposite side of the light emitting surface of the display element, it is preferable that the transparent protective plate on the opposite side of the light emitting surface of the polarizer be the optical plastic film of the present disclosure.

### <Polarizer>

Examples of the polarizer include a sheet-type polarizer formed by stretching an iodine-dyed film (e.g., a polyvinyl alcohol film, a polyvinyl formal film, a polyvinyl acetal film, an ethylene-vinyl acetate copolymer-based saponified film), a wire grid-type polarizer composed of many parallel metal wires, a coated polarizer coated with a lyotropic liquid crystal or dichroic guest-host material, or a multilayer thin-film polarizer. These polarizers may be reflective polarizers with a function of reflecting a non-transmittable polarization component.

The polarizer is preferably arranged so that its absorption axis and any one side of a sample of the optical plastic film cut out according to the above-described procedure are roughly parallel or perpendicular to each other. The term “substantially parallel” means within 0 degrees ±5 degrees, preferably within 0 degrees ±3 degrees, and more preferably within 0 degrees ±1 degree. The term “substantially perpendicular” means within 90 degrees ±5 degrees, preferably within 90 degrees ±3 degrees, and more preferably within 90 degrees ±1 degree.

### Image Display Device

The image display device of the present disclosure includes a display element and a plastic film disposed on the light emitting surface side of the display element, wherein the plastic film is the above-described optical plastic film of the present disclosure.

The image display device of the present disclosure preferably comprises a polarizer between the display element and the optical plastic film of the present disclosure.

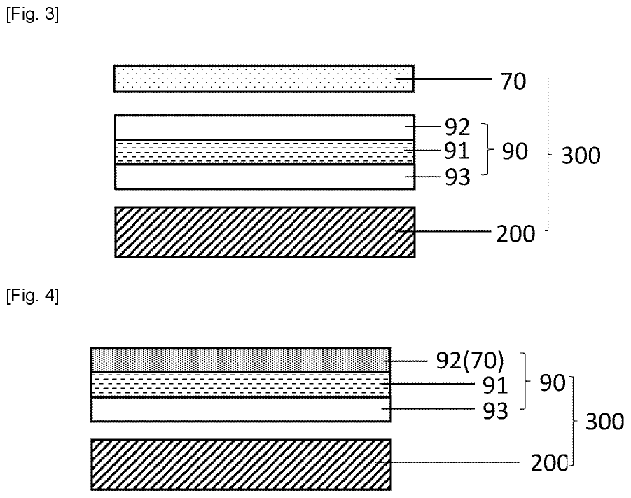

FIGS. 3 and 4 are each a cross-sectional view of an embodiment of image display device 300 in the present disclosure.

Each image display device 300 shown in FIGS. 3 and 4 has an optical plastic film 70 on the light emitting surface side (the upper side of FIGS. 3 and 4) of a display element 200. Each image display device 300 shown in FIGS. 3 and 4 has a polarizer 91 between the display element 200 and the optical plastic film 70. In FIGS. 3 and 4, a first transparent protective plate (92) and a second transparent protective plate (93) are layered on both sides of the polarizer 91. In the image display device shown in FIG. 4, the optical plastic film 70 is used as the first transparent protective plate (92).

The image display device 300 is not limited to the forms shown in FIGS. 3 and 4. For example, in FIGS. 3 and 4, the respective members constituting the image display device 300 are arranged at predetermined intervals. However, the respective members may be integrated by means of an adhesive layer, a pressure-sensitive adhesive layer, or other means. The image display device may have another member(s) (e.g., other plastic films, functional layers, not shown).

### <Display Element>

Examples of the display element include a liquid crystal display element, an EL display element (e.g., an organic EL display element, an inorganic EL display element), or a plasma display element. Further examples include an LED display element (e.g., a micro-LED display element).

When the display element of display device is a liquid crystal display element, a backlight is required on a surface on the side opposite to a resin sheet of the liquid crystal display element.

The image display device may be an image display device with a touch panel function.

Examples of the touch panel include a resistive film-type, electrostatic capacitance-type, electromagnetic induction-type, infrared-type, or ultrasonic-type touch panel.

The touch panel function may be a function added within the display element, such as an in-cell touch panel LCD display element, or a touch panel disposed on the display element.

### <Plastic Film>

The image display device of the present disclosure is provided, on the light emitting surface side of the display element, with the above-described optical plastic film of the present disclosure. In the image display device, there may be only one or two or more optical plastic films of the present disclosure disposed on the light emitting surface side of the display element.

Examples of the plastic film disposed on the light-emitting surface side of the display element include an plastic film used as a base material for various functional films (e.g., a polarizer protection film, a surface protection film, a antireflection film, a conductive film that constitutes a touch panel).

### <Other Plastic Film>

The image display device of the present disclosure may have another plastic film(s) to the extent that they do not interfere with the effects of the present disclosure.

The other plastic film is preferably a optically isotropic film.

### Method for Selecting Optical Plastic Film

The method for selecting the optical plastic film of the present disclosure is:

a method for selecting an optical plastic film comprising a first surface and a second surface that is a surface on a side opposite to the first surface, the method comprising selecting the optical plastic film satisfying the following determination conditions:

the plastic film has an in-plane phase difference of 300 nm or more and 1,450 nm or less; and

in a region within a depth of 20 μm from the first surface in a direction from the first surface to the second surface, an average of an erosion rate is 1.4 μm/g or more.

In the method for selecting the optical plastic film of the present disclosure, the measurement conditions for E₀₋₂₀, the average of the erosion rate, are the same as the measurement conditions for E₀₋₂₀ in the optical plastic film of the present disclosure described above.

The method for selecting the optical plastic film of the present disclosure comprises selecting a plastic film having an in-plane phase difference of 300 nm or more and 1,450 nm or less and E₀₋₂₀ of 1.4 μm/g or more.

Hereinafter, the in-plane phase difference of 300 nm or more and 1,450 nm or less may be referred to as “criterion 1” and the E₀₋₂₀ of 1.4 μm/g or more as “criterion 2”.

In the method for selecting the optical plastic film of the present disclosure, the optical plastic film having favorable pencil hardness without an increase in the in-plane phase difference can be efficiently selected by using the criterion 1 and criterion 2 as determination criteria. In addition, in the method for selecting the optical plastic film of the present disclosure, by using the criterion 1 as the determination criterion it is possible to prevent the plastic film from becoming too thick. Further, in the method for selecting the optical plastic film of the present disclosure, by using the criterion 1 as the determination criterion, it is possible to easily suppress rainbow unevenness when viewed with the naked eyes.

Preferred embodiments of the criteria 1 and 2 are based on the preferred embodiments of the optical plastic film described above.

For example, the lower limit of the in-plane phase difference of the criterion 1 is preferably 350 nm or more, more preferably 400 nm or more, still more preferably 450 nm or more, still more preferably 500 nm or more, still more preferably 510 nm or more, still more preferably 520 nm or more, and still more preferably 550 nm or more, and the upper limit is preferably 1,200 nm or less, more preferably 1,000 nm or less, still more preferably 800 nm or less, still more preferably 700 nm or less, and still more preferably 650 nm or less.

Further, E₀₋₂₀ of the criterion 2 is preferably 1.6 μm/g or more, more preferably 1.8 μm/g or more, still more preferably 1.9 μm/g or more, and still more preferably 2.0 μm/g or more. E₀₋₂₀ of the criterion 2 is also preferably 3.0 μm/g or less, more preferably 2.5 μm/g or less, and still more preferably 2.2 μm/g or less.

The method for selecting the optical plastic film of the present disclosure preferably includes an additional determination condition. Examples of the additional determination condition include an embodiment exemplified as a preferred embodiment in the optical plastic film of the present disclosure described above.

Specific examples of the additional determination conditions include the following conditions. Specifically, the method for selecting an optical plastic film of the present disclosure include one or more selected from the following additional determination conditions.

### <Additional Determination Condition 1>

In the region within a depth of 20 μm from the first surface in a direction from the first surface to the second surface, a ratio of variation of the erosion rate to the average of the erosion rate is 0.100 or less.

### <Additional Determination Condition 2>

When the in-plane phase difference of the plastic film is defined as Re and the phase difference in the thickness direction is defined as Rth, Re/Rth is 0.15 or less.

### <Additional Determination Condition 3>

The plastic film has a phase difference in the thickness direction of 2,000 nm or more.

### <Additional Determination Condition 4>

The plastic film has a JIS K7136:2000 haze of 3.0% or less.

### <Additional Determination Condition 5>

The plastic film has a JIS K7361-1:1997 total light transmittance of 80% or more.

### EXAMPLES

Next, the present disclosure is further described in detail with Examples, but the present discloser is no way limited to these Examples.

### 1. Measurement and Evaluation

The atmosphere for the following measurements and evaluations should be at a temperature of 23° C.±5° C. and a relative humidity of 40% RH or more and 65% RH or less. In addition, samples should be exposed to the above atmosphere for 30 minutes or more and 60 minutes or less before each measurement and evaluation.

### 1-1. In-Plane Phase Difference (Re) and Phase Difference in Thickness Direction (Rth)

Samples with a length of 100 mm×width of 100 mm cut out from optical plastic films of Examples and Comparative Examples produced or prepared in the below-described section “2” to measure the in-plane phase difference and the phase difference in the thickness direction. The measurement instrument used was by using the product name “RETS-100 (measurement spot: 5 mm in diameter)” manufactured by OTSUKA ELECTRONICS CO., LTD.”. Table 1 shows the results.

### 1-2. Rainbow Unevenness

Samples cut out from each Example or Comparative Example (as prepared in the section 1-1) were each arranged on the polarization plate on the viewing side of the image display device as configured below so that the slow-axis direction of the samples was parallel to the horizontal direction of the screen. The image display device was then displayed in white in a dark room environment, observed with the naked eye from a distance of 30 cm or more and 100 cm or less from the image display device, and evaluated for the presence of rainbow unevenness according to the following criteria. The observation angle was in the range of ±45 degrees when the normal direction of the image display device was 0 degrees. The evaluator was a healthy person in his/her 20s. Table 1 shows the results.
A: Rainbow unevenness was not visible.
B: Rainbow unevenness was viewed in a small part of the region
C: Rainbow unevenness was viewed in most of the region.

### <Configuration of Image Display Device>

(1) Backlight light source: White LED
(2) Polarization plate on the light source side: Having TAC films as protective films on both sides of the polarizer made of PVA and iodine. The polarizer is positioned so that the direction of the absorption axis is perpendicular to the horizontal direction of the screen.
(3) Image display cell: Liquid crystal cell
(4) Viewing-side polarization plate: Polarization plate in which a TAC film is used as a polarizer protection film for the polarizer made of PVA and iodine. The polarizer is positioned so that the direction of the absorption axis is perpendicular to parallel direction of the screen.
(5) Size: 10 inches diagonal

### 1-2. Pencil Hardness

A pencil hardness test was conducted on each sample cut out from the optical plastic of each Example or Comparative Example (sample as produced in the section 1-1). The pencil hardness test was performed based on the pencil hardness test specified in JIS K5600-5-4:1999, while the load, speed, and determination conditions were changed from those specified in JIS. Specifically, the load and speed were 100 g and 3 mm/s, respectively. In addition, the requirement for passing the test was that the sample was not scratched at least three times out of five evaluations. For example, when the sample was not scratched 3 times or more out of 5 times at hardness 2B, the sample passed the test at hardness 2B, followed by the test at the next hardness. Table 1 shows the pencil hardness of the samples, as well as the number of times, out of five evaluations, that the sample was not scratched.

The acceptable level is that the sample is not scratched 3 times or more out of 5 evaluations at pencil hardness F.

### 1-3. Measurement of Erosion Rate

A measurement instrument for the erosion rate (MSE testing instrument, product name: “MSE-A203”, manufactured by Palmeso Co., Ltd; the cross-sectional shape of the nozzle is 1 mm×1 mm square; measuring method of the cross-sectional profile: stylus type) was used to measure the erosion rate of the optical plastic film of each Example and Comparative Example and calculate E₀₋₂₀ and σ₀₋₂₀/E₀₋₂₀. The measurement region of the erosion rate was 1 mm×1 mm. Table 1 shows the results.

The measurement of the erosion rate of each sample was performed after the following calibration using a standard acrylic plate. In addition, the test solution was prepared before the calibration, and a dispersion operation was preliminarily performed before the calibration. Further, the standard acrylic plate had an AcE (the average erosion rate of the acrylic plate measured under the measurement condition A) in the specification text in a range of 1.786 μm/g or more and 1.974 μm/g or less.

### (0-1) Preparation of Test Solution

A test solution was prepared by mixing in beakers pure water, a dispersant (the trade name “DEMOL N” from Wako Pure Chemical Industries, Ltd), and the spherical silica having an average particle size (median size) of 3.94 μm (model number “MSE-BS-5-3” designated by Palmeso Co., Ltd; full width at half-maximum of the particle size distribution: 4.2 μm) at a mass ratio of 968:2:30 with a glass rod. After placing the prepared test solution and stirrer in a container (pot), the pot was covered with a lid and a clamp was attached thereto. The pot was then stored in the measurement instrument. In the present Example, the product number “BS5-3” of Potters-Ballotini Co., Ltd. was used as the model number “MSE-BS-5-3” designated by Palmeso Co., Ltd.

### (0-2) Dispersion Operation

After storing the pot containing the test solution in the measurement instrument, a dummy sample was set on the sample mount. Subsequently, the buttons “Erosion Force Setting” and “Do” on the operation panel of the main unit of the measurement instrument were pressed in sequence. Then, predetermined values were entered for the flow rate of the test solution or the compressed air, the pressure of the compressed air, and the pressure of the test solution in the nozzle, and the test solution was jetted onto the dummy sample. After the jet was stopped, the buttons “Return”, “Complete”, and “Confirm” on the same operation panel were pressed in sequence.

### (1) Calibration

An acrylic plate with a thickness of 4 mm, the calibration sample, was fixed to a sample mount of the measurement instrument via a double-sided tape (“Kapton double-stick tape”, product name: P-223 1-6299-01, manufactured by Nitto Denko America, Inc.). The acrylic plate was a PMMA plate.

Next, the sample mount to which the acrylic plate was fixed was set in the measurement instrument.

Next, the micro gauge was unlocked and the height of the sample mount was adjusted with a height gauge. The distance between the jet hole of the measurement instrument and the acrylic plate was adjusted to 4 mm.

Next, the button “To the treatment condition input screen” on the operation panel of the main unit of the measurement instrument was pressed, and then set to “Number of Steps: 1, Specified jet amount g×1 time”. The amount jetted was set to 4 g.

Next, the buttons “Setup Complete,” “Start Operation,” and “Yes” on the same operation panel were pressed in sequence. The flow rate of the test solution or the compressed air, the pressure of the compressed air, and the pressure of the test solution in the nozzle were maintained at the values entered in the section “(0-2) Dispersion Operation”.

Next, the “ Online” of the operation screen of the data processing PC was clicked to cancel the online mode and change the mode to the offline mode.

Next, the “Descending” of the same operation screen was clicked, and the stylus of the stylus step gauge of the cross-sectional profile acquisition unit was descended.

Next, the micro gauge was turned up after confirming that the micro gauge was unlocked. At this time, the micro gauge was adjusted so that the red arrow on the monitor was centered. This adjustment allows the stylus of the stylus step gauge to make contact with the surface of the calibration sample and adjust the zero point of the z-axis, the height direction.

Next, the micro-gauge lock was switched from unlocked (off) to on. Next, the “Ascending” was clicked, and the stylus of the stylus step gauge of the sectional profile acquisition unit was ascended.

Next, the “Offline” of the operation screen of the data processing PC was clicked to cancel the offline mode and change the mode to the online mode.

Next, the cover of the main unit of the measurement instrument was closed, and the button “Confirm” on the operation panel of the main unit of the measuring instrument was pressed to jet 4 g of the test solution.

After the jetting of the test solution was stopped, “Do” was clicked, and the erosion rate was calculated. If the erosion rate is within ±5% of 1.88 (μm/g) as a reference, calibration was completed. Meanwhile, if the erosion rate was out of the range, the flow rate of the test solution, the flow rate of the compressed air, the pressure of the compressed air, and the pressure of the test solution in the nozzle were adjusted, and calibration was repeated until the erosion rate was within the range.

### (2) Measurement of Erosion Rate of Each Sample

### (2-1) Attachment of Sample

A laminate was prepared by layering samples (plastic films of Examples and Comparative Examples) onto a stainless steel plate, and the laminate was fixed to a sample mount via a double-sided tape (“Kapton double-stick tape”, product name: P-223 1-6299-01, manufactured by Nitto Denko America, Inc.). The sample had a size of 1 cm×1 cm.

Next, the sample mount was set in the measurement instrument. The micro gauge was then unlocked, and the height of the sample mount was adjusted with a height gauge. The distance between the jet hole of the measurement instrument and the plastic film was adjusted to 4 mm.

Next, the button “To the treatment condition input screen” on the operation panel of the main unit of the measurement instrument was pressed, and the number of steps was entered, and the amount of the test solution jetted (g/time) was entered for each step. The amount jetted for each step was set within the range of 0.5 g or more and 3.0 g or less. The flow rate of the test solution or the compressed air, the pressure of the compressed air, and the pressure of the test solution in the nozzle were maintained under the conditions passed in, the section “(1) Calibration”.

Next, the buttons “Setup Complete,” “Start Operation,” and “Yes” on the same operation panel were pressed in sequence.

Next, the “ Online” of the operation screen of the data processing PC was clicked to cancel the online mode and change the mode to the offline mode.

Next, the “Descending” of the same operation screen was clicked, and the stylus of the stylus step gauge of the cross-sectional profile acquisition unit was descended.

Next, the micro gauge was turned up after confirming that the micro gauge was unlocked. At this time, the micro gauge was adjusted so that the red arrow on the monitor was centered. This adjustment allows the stylus of the stylus step gauge to make contact with the surface of the calibration sample and adjust the zero point of the z-axis, the height direction.

Next, the micro-gauge lock was switched from unlocked (off) to on.

Next, the “Ascending” was clicked, and the stylus of the stylus step gauge of the sectional profile acquisition unit was ascended.

Next, the “Offline” of the operation screen of the data processing PC was clicked to cancel the offline mode and change the mode to the online mode.

### (2-2) Start of Measurement

The cover of the main unit of the measurement instrument was closed, the button “Confirm” on the operation panel of the main unit of the measurement instrument was pressed, and a measurement cycle consisting of jet of the test solution and measurement of the cross-sectional profile was performed until the depth of the cross-sectional profile exceeded 20 μm. Specifically, the measurement was performed until the depth of the cross-sectional profile reached 25 μm or more and 30 μm or less.

After the measurement, the attached software “MseCalc” was started and “Analysis Method” was clicked. Next, “ Analysis of Average Value” was clicked. Then, “A-1” and “A-2” were displayed in the “Analysis Name” column by clicking “Add” twice on the screen of analysis of the average value. The “Criteria” column of “A-1” was double-clicked to display “0” in the “Criteria” column.

Next, “A-1” on the screen of analysis of the average value is clicked to activate it, and the position of the X-axis position bar is manipulated. The position of the position bar is determined at the point in the cross-sectional profile screen where the plastic film is not worn.

Next, A-2 on the screen of analysis of the average value is clicked to activate it, and the position of the X-axis position bar is manipulated. The position of the position bar is determined at the deepest point in the cross-sectional profile screen where the plastic film is worn.

Next, the cross-sectional profile and erosion rate data for each step were output in csv format to calculate the erosion rate E₀₋₂₀. Specifically, among the csv output data, the “erosion rate (corrected)” whose depth was 0 μm or more and 20 μm or less was averaged to calculate the erosion rate E₀₋₂₀.

### 2. To Produce and Prepare Stretched Polyester Film

### Example 1

First, 1 kg of PET (melting point: 258° C.; absorption center wavelength: 320 nm) and 0.1 kg of UV absorber (2,2′-(1,4-phenylene)bis(4H-3,1-benzoxazinon-4-one)) were melt-mixed at 280° C. in a kneader to produce a pellet containing the UV absorber. The pellet and PET with a melting point of 258° C. were fed into a single screw extruder, melted and kneaded at 280° C., and extruded through a T-die to prepare a casting film by casting on a cast drum with a controlled surface temperature of 25° C. The amount of UV absorber in the casting film was 1 part by mass per 100 parts by mass of PET.

The resulting casting film was heated by a group of rolls set at 95° C. and then stretched 3.6 times in the flow direction while being heated by a radiation heater so that the temperature of the film surface at the 180-mm point in the 480-mm stretching section (having a starting point with a stretching roll A and an ending point with a stretching roll B, each of which has two nip rolls) was 103° C., and then once cooled. In Example 1, the time required for the casting film to pass through the stretching section in the flow direction was 0.192 seconds.

Subsequently, corona discharge treatment was applied to both sides of this uniaxially stretched film in air to set the wetting tension of the base film to 55 mN/m. The corona discharge treated surfaces on the both sides of the film were in-line coated with a “lubricative layer coating liquid containing polyester resin with a glass transition temperature of 18° C., polyester resin with a glass transition temperature of 82° C., and silica particles with an average particle size of 100 nm” to form each lubricative layer.

Next, the uniaxially stretched film was guided to a tenter, preheated with hot air at 95° C., and stretched 4.9 times in the width direction at 105° C. in the first stage and 140° C. in the second stage. Here, when the stretching section in the width direction was divided into two sections, the film was stretched in two steps so that the amount of film stretch at the midpoint of the stretching section in the width direction (film width at measurement point—film width before stretching) was 80% of the amount of stretch at the end of the stretching section in the width direction.

When the film was stretched in the width direction, the surface temperature of the film was controlled as described in (1) and (2) below.
(1) The film surface temperature was controlled to 90° C. or more and 110° C. or less when the stretching ratio in the width direction is in the range of 1 time or more and less than 3.5 times.
(2) The film surface temperature was controlled to 105° C. or more and 130° C. or less when the stretching ratio in the width direction is in the range of 3.5 times or more.

The film stretched in the width direction was heat-treated with hot air as it is at a heat treatment temperature raised stepwise from 180° C. to 245° C. in a tenter. Subsequently, 1% relaxation treatment was applied in the width direction under the same temperature conditions. Further, the film was quickly cooled to 100° C., followed by another 1% relaxation treatment in the width direction and then rolled up to obtain an optical plastic film (biaxially stretched polyester film with a thickness of 40 μm) of Example 1.

### Example 2

An optical plastic film (biaxially stretched polyester film with a thickness of 40 μm) of Example 2 was produced by the same procedure as in Example 1, except that the stretching section in the flow direction was changed from 480 mm to 460 mm, and the stretching ratio in the width direction was changed from 4.9 times to 5.0 times. In Example 2, the time required for the casting film to pass through the stretching section in the flow direction was 0.184 seconds.

### Example 3

An optical plastic film (biaxially stretched polyester film with a thickness of 50 nm) of Example 3 was produced by the same procedure as in Example 1, except that the casting film of Example 1 was thickened, the stretching section in the flow direction was changed from 480 mm to 450 mm, and the stretching ratio in the width direction was changed from 4.9 times to 5.1 times. In Example 3, the time required for the casting film to pass through the stretching section in the flow direction was 0.180 seconds.

### Example 4

An optical plastic film (biaxially stretched polyester film with a thickness of 45 nm) of Example 4 was produced by the same procedure as in Example 1, except that the casting film of Example 1 was thickened, the stretching section in the flow direction was changed from 480 mm to 440 mm, and the stretching ratio in the width direction was changed from 4.9 times to 5.0 times. In Example 4, the time required for the casting film to pass through the stretching section in the flow direction was 0.176 seconds.

### Example 5

An optical plastic film (biaxially stretched polyester film with a thickness of 40 nm) of Example 5 was produced by the same procedure as in Example 1, except that the stretching section in the flow direction was changed from 480 mm to 485 mm. In Example 5, the time required for the casting film to pass through the stretching section in the flow direction was 0.194 seconds.

### Comparative Example 1

A commercially available biaxially stretched polyester film (product name: Cosmoshine A4300; thickness: 38 μm, manufactured by Toyobo Co., Ltd.) was prepared as an optical plastic film of Comparative Example 1.

### Comparative Example 2

A commercially available uniaxially stretched polyester film (product name: Cosmoshine TA044; thickness: 50 μm, manufactured by Toyobo Co., Ltd.) was prepared as an optical plastic film of Comparative Example 2.

### Comparative Example 3

An optical plastic film (biaxially stretched polyester film with a thickness of 40 μm) of Comparative Example 3 was produced by the same procedure as in Example 1, except that the stretching section in the flow direction was changed from 480 mm to 430 mm. In Comparative Example 3, the time required for the casting film to pass through the stretching section in the flow direction was 0.172 seconds.

TABLE 1

| | | Example | | | | | Comparative Example | | |
|---|---|---|---|---|---|---|---|---|---|
| | | 1 | 2 | 3 | 4 | 5 | 1 | 2 | 3 |
| In-plane phase difference (Re) [nm] | | 570 | 731 | 1118 | 1090 | 510 | 1591 | 10302 | 1046 |
| Phase difference in thickness | | 6146 | 6898 | 8402 | 8030 | 6025 | 5615 | 12045 | 9096 |
| direction (Rth) [nm] | | | | | | | | | |
| Thickness of plastic film [μm] | | 40 | 40 | 50 | 45 | 40 | 38 | 50 | 40 |
| Re/Rth | | 0.09 | 0.11 | 0.13 | 0.14 | 0.08 | 0.28 | 0.86 | 0.12 |
| E₀₋₂₀ [μm/g] | | 2.03 | 1.92 | 1.70 | 1.53 | 1.88 | 0.99 | 1.03 | 1.32 |
| σ₀₋₂₀/E₀₋₂₀ | | 0.043 | 0.053 | 0.072 | 0.069 | 0.038 | 0.126 | 0.106 | 0.110 |
| Evaluation | Evaluation of | F | F | F | F | F | 3B | 2B | HB |
| | pencil hardness | (5/5) | (5/5) | (4/5) | (3/5) | (5/5) | (5/5) | (5/5) | (4/5) |
| | Pass/fail of | Passed | Passed | Passed | Passed | Passed | Failed | Failed | Failed |
| | pencil hardness | | | | | | | | |
| | Rainbow unevenness | A | A | B | B | A | C | A | B |

The results of Table 1 have demonstrated that the optical plastic film of each Example can have favorable pencil hardness without an increase in the in-plane phase difference.

Although not evaluated in the table, the optical plastic film of each Example could be used without any problems as a base material for various functional films (e.g., a polarizer protection film, a surface protection film, an anti-glare film, an anti-reflection film, a conductive film that constitutes a touch panel). Although not evaluated in the table, the optical plastic film of each Example was able to be used without any problems as a member in the production of the functional films.

### REFERENCE SIGNS LIST

11: Container
12: Receptor
21: Piping for test solution
22: Piping for compressed air
23: Return piping
24: Return pump
31, 32: Flowmeter
41, 42: Pressure gauge
50: Jetting section
51: Nozzle
52: Housing
60: Cross-sectional profile acquisition unit
70: Optical plastic film
81: Sample mount
82: Support
100: Erosion rate measuring instrument
A1: Water
A2: Spherical silica
A3: Air
A4: Worn optical plastic film
90: Polarization plate
91: Polarizer
92: First transparent protective plate
93: Second transparent protective plate
200: Display element
300: Image display device

1. An optical plastic film comprising a first surface and a second surface that is a surface on a side opposite to the first surface, wherein
the plastic film has an in-plane phase difference of 300 nm or more and 1,450 nm or less, and
in a region within a depth of 20 μm from the first surface in a direction from the first surface to the second surface, an average of an erosion rate is 1.4 μm/g or more.

2. The optical plastic film according to claim 1, wherein in the region within a depth of 20 μm from the first surface in the direction from the first surface to the second surface, a ratio of variation of the erosion rate to the average of the erosion rate is 0.100 or less.

3. The optical plastic film according to claim 1, wherein when the in-plane phase difference of the plastic film is defined as Re and the phase difference in the thickness direction is defined as Rth, Re/Rth is 0.15 or less.

4. A polarization plate comprising: a polarizer; a first transparent protective plate disposed on one side of the polarizer; and a second transparent protective plate disposed on the other side of the polarizer, wherein at least one selected from the group consisting of the first transparent protective plate and the second transparent protective plate is the optical plastic film according to claim 1.

5. An image display device comprising a display element and a plastic film disposed on a light emitting surface side of the display element, wherein the plastic film is the optical plastic film according to claim 1.

6. The image display device according to claim 5, comprising a polarizer between the display element and the plastic film.

7. A method for selecting an optical plastic film comprising a first surface and a second surface that is a surface on a side opposite to the first surface, the method comprising selecting the optical plastic film satisfying the following determination conditions:
the plastic film has an in-plane phase difference of 300 nm or more and 1,450 nm or less; and
in a region within a depth of 20 μm from the first surface in a direction from the first surface to the second surface, an average of an erosion rate is 1.4 μm/g or more.
